(19) United States
(12) Patent Application Publication
(10) Pub. No.: US 2005/0077285 A1
(43) Pub. Date: Apr. 14, 2005

(54) Device for homogeneous heating of an object

(75) Inventors: Babak Heidari, Furulund (SE); Lars Montelius, Bjarred (SE)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Obducat Aktiebolag

(21) Appl. No.: 10/958,588

(22) Filed: Oct. 6, 2004

Related U.S. Application Data
(62) Division of application No. 10/204,631, filed on Nov. 26, 2002, now abandoned.

(30) Foreign Application Priority Data
Feb. 23, 2000 (SE) 0000574-4

(51) Int. Cl. H01L 29/792

(52) U.S. Cl. 219/444.1

(57) ABSTRACT

A device for homogeneous heating of an object comprises a supporting surface for supporting the object, and a heating layer arranged on the supporting surface. The heating layer absorbs at least partly energy received from a radiation source and emits at least partly the thus-absorbed energy to the object supported on the supporting surface. The layer is made of a material such that the energy absorbed by the layer is in a self-regulating manner distributed uniformly along the surface of the layer. The heating device forms a simple and compact unit which can be used to rapidly heat the object to a homogeneous temperature.

### FIELD OF THE INVENTION

The present invention relates generally to heating of objects and more specifically to heating with stringent requirements that a homogeneous distribution of temperature be achieved in the heated object.

The invention is specifically, but not exclusively, directed at the manufacture of micro- and nanostructures. Consequently, the following is a description of background art, objects and embodiments related to the present invention with reference to such manufacture, in particular nanoimprint lithography. However it should be appreciated that the invention is also suitable for heating of objects in other cases.

### BACKGROUND ART

A promising technique for manufacturing nanostructures, i.e. structures having a size of 100 nm and less, is so-called nanoimprint lithography. This technique is described in the document U.S. Pat. No. 5,772,905 which is incorporated herewith by reference. In such nanoimprint lithography, the mould, which is provided with a pattern of nanostructures, is pressed into a thin film of a polymer material (resist), which is applied to a substrate, whereby recesses form in the film in conformity with the pattern of the mould. Subsequently, any remaining film in the recesses is removed so that the substrate is exposed. In the subsequent process steps, the pattern in the film is reproduced in the substrate or in another material supplied to the substrate.

For acceptable results in such manufacture of nanostructures, the film applied to the substrate must be heated extremely homogeneously before the mould is pressed into the film. Variations in temperature along the surface of the film should thus be minimised. Moreover, it should be possible to exactly control the temperature of the film to a given value. For reasons of production, it is also desirable for the heating of the film to be quick. At present there is no heating equipment that satisfies these requirements.

### SUMMARY OF THE INVENTION

An object of the invention is to wholly or partly satisfy the requirements identified above. More specifically, an object of the present invention is to provide a device which allows homogeneous heating of an object.

It is also an object of the invention to provide a device which is capable of homogeneously heating an object exactly to a given temperature.

Another object of the invention is to provide a device which allows homogeneous heating of an object to a given temperature in a short time.

A further object of the invention is to provide a device which allows homogeneous heating of an object and the construction of which is simple.

One more object of the invention is to provide a device which allows homogeneous heating of an object in vacuum.

These and other objects that will appear from the following description are now achieved by means of a device according to claim 1. Preferred embodiments are defined in the dependent claims.

Owing to the fact that the energy absorbed in the layer is in a self-regulating manner uniformly distributed along the surface, this energy will be emitted very uniformly from the surface of the layer to the object. Thus, the object can be homogeneously heated to a given temperature.

According to an embodiment, the layer is made of a material whose absorption of the received energy decreases as the temperature rises. Thus, uniform distribution of the absorbed energy in the layer is achieved automatically. If the temperature rises in part of the layer, the absorption of energy in fact decreases automatically in that part relative to the other parts of the layer.

According to a further embodiment, the layer is of such a thickness that transport of the received energy essentially takes place along the surface. Consequently the received energy is forced to be distributed along the surface, thereby achieving rapid equalization of energy over the surface of the layer.

According to a preferred embodiment, the layer is adapted to receive electric energy, which is converted into thermal energy owing to resistive losses in the layer. This embodiment allows a simple and compact design of the heating device. Preferably, the layer is made of an electrically conductive material whose resistivity increases with a rising temperature. Thus, uniform distribution of the thermal energy formed in the layer is automatically achieved. If the temperature rises in part of the layer, the current supplied to the layer from the source will in fact mainly be conducted to the other layer parts, the temperature of which thus rises. It is also preferable that the material has high electric resistivity, preferably at least about 50 μΩcm (at a reference temperature of 20° C.) and most preferably at least about 500 μΩcm (at a reference temperature of 20° C.), so that a large amount of the supplied electric energy is converted into thermal energy in the layer. Consequently, the thickness of the layer can be kept down, whereby the layer quickly adopts a temperature which is uniformly distributed along the surface of the layer. Of course, the material must not have such high electric resistivity as to serve as an electric insulator.

According to one more preferred embodiment, the material is carbon, preferably graphite. This material can easily be formed to thin layers and has a high melting point and high resistivity. Moreover, it is inclined to spontaneously form insulating oxides. It is preferred for the thickness of the carbon layer to be less than about 1 mm, preferably less than about 0.1 mm. These dimensions have been found to give sufficient heat development while at the same time the transport of current in the layer essentially takes place along the surface.

According to a preferred embodiment, the layer is arranged essentially parallel with the supporting surface, whereby the energy absorbed in the layer can be transferred uniformly to the object.

It is also preferable that a thermally insulating element is arranged at the side of the layer facing away from the supporting surface. Thus, the energy emitted from the layer is directed towards the supporting surface, so that the transfer of energy to the object will be optimised.

According to an alternative embodiment of the invention, the layer is heated by radiation from a lamp, whose wavelength is adapted to absorption in the layer. The lamp is suitably arranged at the side of the layer facing away from the supporting surface.

According to one more alternative embodiment of the present invention, the layer is heated by means of ultrasound whose wavelength is adjusted so as to be absorbed in the layer. The ultrasonic source is advantageously arranged at the side of the layer facing away from the supporting surface.

### BRIEF DESCRIPTION OF THE DRAWINGS

The invention and its advantages will be described in more detail below with reference to the accompanying schematic drawing, which by way of example illustrates currently preferred embodiments of the invention.

FIG. 1 is a side view of a heating device according to a first embodiment of the invention, in which electric energy is supplied to the layer.

FIG. 2 is a side view of a heating device according to a second embodiment of the invention, in which radiation energy is supplied to the layer.

FIG. 3 is a side view of a heating device according to a third embodiment of the invention, in which sound energy is supplied to the layer.

### DESCRIPTION OF PREFERRED EMBODIMENTS

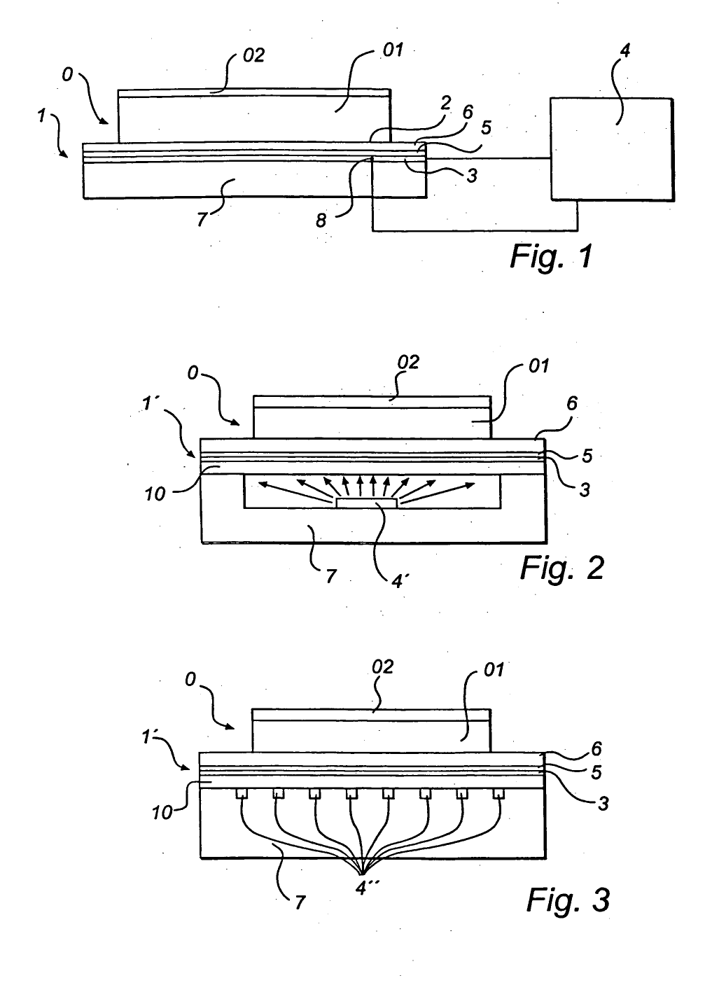

FIG. 1 shows a first embodiment of an inventive heating device 1 which on a supporting surface 2 supports an object O that is to be heated. In the shown examples, which schematically illustrate the use of the heating device in nanoimprint lithography, the object O consists of a substrate O1 of silicon/silicon dioxide and a polymer layer O2 applied thereto. The device 1 comprises a heating layer 3 of graphite, which is connected to a power source 4. The source 4 produces an electric circuit with the heating layer 3 and is activatable to supply electric current through this layer. The surface of the heating layer 3 is of at least the same size as the supporting surface 2. In this embodiment, the heating layer 3 is of a uniform thickness of about 0.1 mm. At the side of the heating layer 3 facing the supporting surface 2 an electrically insulating layer 5 is arranged, on the outside of which a rigid supporting plate 6 is arranged, which forms the supporting surface 2 for the object O and protects the electrically insulating layer 5 and the heating layer 3 from being damaged. In the shown example, the supporting plate 6 is made of aluminium and the electrically insulating layer 5 consists of a layer of aluminium dioxide formed on the supporting plate 6. At the side of the heating layer 3 facing away from the supporting surface 2 there is arranged a thermally insulating plate 7 of Nefalit, i.e. a thermally stable composite consisting of aluminium oxide, ceramic fibres and air. A temperature sensor 8 detects the temperature in the heating layer 3, and temperature information from the sensor 8 is fed back to the power source 4 to control its supply of energy.

Since graphite is a material having a positive temperature coefficient, i.e. its resistitivity increases with an increasing temperature, the major part of the current supplied to the heating layer 3 from the voltage source 4 will continuously and in a self-regulating manner be directed to the areas of the heating layer 3 which have the lowest temperature. Consequently the energy distribution, as well as the temperature distribution, along the surface of the heating layer 3 will be very uniform. This uniformly distributed energy is conducted, via the electrically insulating layer 5 and the supporting plate 6, into the object O, which is homogeneously heated. Heating takes place very quickly thanks to the small mass of the heating layer 3.

Tests have presented excellent results. In one test, the device 1 was used to heat a substrate of silicon/silicon dioxide having a thickness of 300 μm. A plurality of temperature sensors (not shown) were mounted in different areas of the side of the substrate facing away from the supporting surface 2 to measure the temperature uniformity of the substrate during and after the heating process. Using the inventive device 1, the substrate was heated from 20° C. to 200° C. in less than about 10 s and from 20° C. to 1000° C. in less than about 1 min. The variation in temperature within an area of 50 mm was less than ±1° C. over the surface of the substrate.

It goes without saying that other materials than graphite can be used in the heating layer 3, for instance a suitable metal or metal composite having a positive temperature coefficient. However the resistivity of the material of the layer should be relatively high, so that sufficient generation of heat can be obtained with layer thicknesses in the order of 1 mm or less. In too thick heating layers 3, the current is not conducted essentially along the surface, but also in depth, which results in undesirably slow equalisation of temperature in the layer 3. A resistivity of at least about 50 μΩcm (at a reference temperature of 20° C.) and most preferably at least about 500 μΩcm (at a reference temperature of 20° C.), would be convenient.

The thermally insulating plate 7 is exposed to high temperatures and aims at retroreflecting thermal energy emitted from the heating layer 3 and, thus, conducting practically all emitted thermal energy towards the supporting surface 2. A person skilled in the art understands that there are a great many suitable materials although Nefalit has at present been found to give optimum results. Examples of other suitable materials are aluminium oxide and various ceramics, e.g. Macor.

The supporting plate 6, which can be dispensed with, should have uniform thickness and allow high heat transport from the layer 3 to the supporting surface 2. The electrically insulating layer 5 can be arranged in an optional manner, for instance in the form of an oxide applied directly to the heating layer 3. For the thermal energy emitted from the layer 3 to be transferred uniformly to the object O, the heating layer 3, the electrically insulating layer 5 and the supporting plate 6 should, however, be plane, parallel with each other and arranged against each other.

FIG. 2 shows an alternative embodiment of a heating device 1′ according to the invention. Parts corresponding to those of the heating device 1 described above have been given the same reference numerals and will not be further described in the following.

The heating device 1′ comprises a built-in radiation source 4′, e.g. an IR source, which is arranged to radiate the heating layer 3 for inducing thermal energy into the same. In this case, the heating layer 3 is made of a material whose absorption of the incident radiation energy decreases as the temperature rises. Thus, a very uniform energy distribution, as well as temperature distribution, can be achieved along the surface of the layer 3. Since also in this embodiment the heating layer 3 should be thin, a supporting element 10, which is transparent to radiation, is arranged between the source 4′ and the layer 3 for supporting the latter. In the case involving a source 4′ for emitting infrared (IR) radiation, the supporting element 10 can be made of e.g. SiC which has a suitable band gap in the radiation area in question.

FIG. 3 shows a second alternative embodiment of a heating device 1″ according to the invention. Parts corresponding to those of the heating device 1 described above have been given the same reference numerals and will not be further described in the following.

The heating device 1″ comprises a plurality of built-in ultrasonic sources 4″, such as piezoelectric elements, which are adapted to emit ultrasonic waves to the heating layer 3 for inducing thermal energy into the same. In this case, the heating layer 3 is made of a material whose absorption of the incident sound energy decreases as the temperature rises. Thus, a very uniform energy distribution, as well as temperature distribution, can be achieved along the surface of the layer 3. Since also in this embodiment the heating layer 3 should be thin, a supporting element 10, which is transparent to the sound waves, is arranged between the sources 4″ and the layer 3 for supporting the latter.

The inventive device 1, 1′ is extremely well suited for heating a polymer layer applied to a substrate in nanoimprint lithography, but is useful in all kinds of heating where a high degree of temperature uniformity is desired in the heated object. Since the device 1, 1′ can be used for heating an object in vacuum, also in high vacuum, it will be very useful in the production of micro- and nanostructures, for instance for baking a resist material in the manufacture-of semiconductors, heating a substrate in epitaxy and heating a substrate when metallising it. Moreover, the device 1, 1′ is well suited to provide a coating of an object, for instance by applying a meltable material or a solvent to the object and heating the object so that the material/the solvent forms said coating thereof.

Finally, it should be emphasised that the invention is in no way restricted to the embodiments described above and that several modifications are feasible within the scope of the appended claims. For instance, the device may comprise a plurality of heating layers arranged side by side and/or on top of each other.

1-21. (canceled)

22. A device for homogeneous heating of an object, the device comprising:
a supporting surface for supporting the object;
a radiation source; and
a layer connected to the supporting surface, wherein the layer is arranged to absorb energy received from the radiation source and to at least partly conduct the absorbed energy to the object supported on the supporting surface, the layer being made of a material such that the energy absorbed by the layer is distributed uniformly along a surface of the layer in a self-regulating manner.

23. The device as claimed in claim 22, wherein the layer is arranged to receive radiation energy from the radiation source for inducing thermal energy in the layer.

24. The device as claimed in claim 22, wherein the material has a coefficient of absorption of incident radiation energy and wherein the coefficient decreases as the temperature rises.

25. The device as claimed in claim 22, wherein the layer comprises a layer of carbon.

26. The device as claimed in claim 22, wherein the layer comprises a layer of graphite.

27. The device as claimed in claim 22, wherein the layer has such a thickness that the transport of the received energy essentially takes place along the surface of the layer.

28. The device as claimed in claim 27, wherein the layer has a thickness which is less than about 1 mm.

29. The device as claimed in claim 27, wherein the layer has a thickness which is less than about 0.1 mm.

30. The device as claimed in claim 22, wherein the layer is arranged substantially parallel with the supporting surface.

31. The device as claimed in claim 22, wherein a thermally insulating element is arranged at a side of the layer facing away from the supporting surface.

32. The device as claimed in claim 22, wherein a supporting element is arranged between the layer and the radiation source and supports the layer.

33. The device as claimed in claim 32, wherein the supporting element is transparent to radiation from the radiation source.

34. The device as claimed in claim 32, wherein the supporting element is made from SiC.

35. The device as claimed in claim 34, wherein the radiation source is arranged to emit infrared radiation.

36. The device as claimed in claim 22, wherein a rigid protective element is arranged at a side of the layer facing the supporting surface.

37. The device as claimed in claim 36, wherein the protective element allows a high degree of heat transport from the layer to the supporting surface.

38. A method for heating an object, comprising:
supporting the object on a supporting surface of a heating device;
emitting radiation from a radiation source onto a layer connected to the supporting surface, wherein the radiation received from the radiation source is at least partly absorbed by the layer and induced as thermal energy, the layer being made of a material such that the energy absorbed by the layer is distributed uniformly along the surface in a self-regulating manner; and
conducting the absorbed energy to the object through the supporting surface to homogeneously heat the object.

39. A method for heating objects in nanoimprint lithography, comprising:
providing a polymer layer on a substrate;
supporting the substrate on a supporting surface of a heating device;
emitting radiation from a radiation source onto a layer connected to the supporting surface, wherein the radiation received from the radiation source is at least partly absorbed by the layer and induced as thermal energy, the layer being made of a material such that the energy absorbed by the layer is distributed uniformly along the surface in a self-regulating manner; and
conducting the absorbed energy to the substrate through the supporting surface to homogeneously heat the polymer layer.

40. A method for baking a resist material in the manufacture of semiconductors, comprising:
providing an object comprising a resist layer;
supporting the object on a supporting surface of a heating device;
emitting radiation from a radiation source onto a layer connected to the supporting surface, wherein the radiation received from the radiation source is at least partly absorbed by the layer and induced as thermal energy, the layer being made of a material such that the energy absorbed by the layer is distributed uniformly along the surface in a self-regulating manner; and
conducting the absorbed energy to the object through the supporting surface to homogeneously heat the resist layer.

41. A method for heating a substrate in epitaxy, comprising:
supporting the substrate on a supporting surface of a heating device;
emitting radiation from a radiation source onto a layer connected to the supporting surface, wherein the radiation received from the radiation source is at least partly absorbed by the layer and induced as thermal energy, the layer being made of a material such that the energy absorbed by the layer is distributed uniformly along the surface in a self-regulating manner; and
conducting the absorbed energy to the substrate through the supporting surface to homogeneously heat the substrate.

42. A method for heating and metallizing a substrate, comprising:
supporting the substrate on a supporting surface of a heating device;
emitting radiation from a radiation source onto a layer connected to the supporting surface, wherein the radiation received from the radiation source is at least partly absorbed by the layer and induced as thermal energy, the layer being made of a material such that the energy absorbed by the layer is distributed uniformly along the surface in a self-regulating manner; and
conducting the absorbed energy to the substrate through the supporting surface to homogeneously heat the substrate.

43. A method for coating an object, comprising the steps:
applying a meltable material on the object;
supporting the object on a supporting surface of a heating device;
emitting radiation from a radiation source onto a layer connected to the supporting surface, wherein the radiation received from the radiation source is at least partly absorbed by the layer and induced as thermal energy, the layer being made of a material such that the energy absorbed by the layer is distributed uniformly along the surface in a self-regulating manner; and
conducting the absorbed energy to the object through the supporting surface to homogeneously heat the substrate and to form a coating of the material on the object.

44. The method as claimed in claim 43, wherein the material is a solvent.
